(19) United States
(12) Patent Application Publication
(10) Pub. No.: US 2023/0018862 A1
(43) Pub. Date: Jan. 19, 2023

(54) PHOTO-LITHOGRAPHED ARRAY OF LIGHT-EMITTING AND LIGHT-CONVERTING DEVICES

(71) Applicant: Sharp Display Technology Corporation, Kameyama City (JP)

(72) Inventors: Alessandro Minotto, Oxford (GB); Andrea Zampetti, Oxford (GB); Valerie Berryman-Bousquet, Oxford (GB)

(21) Appl. No.: 17/377,655

(22) Filed: Jul. 16, 2021

(51) Int. Cl. H01L 27/32; H01L 51/50; H01L 27/144

(52) U.S. Cl. CPC H01L 27/3246; H01L 51/502; H01L 27/1446; H01L 27/3211

(57) ABSTRACT

A sub-pixel array device includes a plurality of optoelectronic devices disposed on a substrate, the plurality of optoelectronic devices including a light-emitting device and a light-converting device, and a bank structure that separates adjacent optoelectronic devices. Each optoelectronic device includes a first electrode, a second electrode, an active layer disposed between the electrodes and including a solution processable semiconductor, and a photo-crosslinkable material disposed between the first electrode and the second electrode. The photo-crosslinkable material may be incorporated within the active layer of each of the plurality of optoelectronic devices, so as to form a light-emitting device having a photo-crosslinkable emissive layer and a light-converting device having a photo-crosslinkable photo-active layer. The photo-crosslinkable material may be disposed between the active layer and the second electrode, such as incorporated within a capping layer or a charge transport layer disposed between the active layer and the second electrode.

### TECHNICAL FIELD

This present application relates to optoelectronic devices, and in particular to high-resolution, multicolor, and multifunction displays, incorporating quantum dot light-emitting diodes and light-converting devices.

### BACKGROUND ART

Among the different emerging technologies that are currently being developed in the field of high-resolution displays, quantum dot (QD) light-emitting diode (QLED) displays represent a promising platform to combine light-emission and light-converting functionalities. A typical architecture for a QLED includes an anode acting as hole injection electrode; a hole transport layer (HTL) disposed on the anode; an emissive layer (EML) containing QDs as an emissive material disposed on the HTL; an electron transport layer (ETL) disposed on the EML; and a cathode acting as an electron injection electrode disposed on the ETL. When a forward bias is applied between the anode and cathode, holes and electrons are transported within the device through the HTL and ETL, respectively. The holes and electrons recombine in the QD EML, which emits light. Light is ultimately emitted from the device provided at least one of the electrodes is semitransparent. The architecture of a QLED resembles the architecture of an OLED, in which the EML contains an organic semiconductor. Furthermore, organic semiconductors are typically integrated in the HTL of QLEDs, and often also in the EML and ETL. For this reason, QLEDs can be considered as hybrid organic-inorganic light-emitting diodes.

Generally, QDs employed in QLEDs include ligands bound to their surface, which passivate the QD surface and enable deposition of the QDs via solution process techniques. Solution process methods allow easy and cheap large-scale deposition and thus are preferable to more complex and costly thermal evaporation methods commonly used for OLEDs. For the fabrication of a multicolor high-resolution display based on arrays of QLEDs, three different types of electroluminescent QDs emitting red (R), green (G), and blue (B) light need to be deposited on three different regions of a substrate, to form R, G, and B sub-pixels.

To enable the selective deposition of QLEDs in a patterned sub-pixel arrangement, U.S. Pat. No. 10,581,007 (Angioni et al., issued Mar. 30, 2020), which is commonly assigned to the current Applicant, teaches an emissive layer comprising QDs, with the QDs dispersed in a photo-crosslinked matrix based on one or more photo-crosslinkable materials. When any of such photo-crosslinkable materials is also a charge transport material, the blended layer forms a combined charge transport and emissive layer (CCTEL).

In recent years, the integration of high-resolution display technologies into various kinds of portable electronic devices has stimulated the development of display devices with multiple functionalities. For example, display devices have been developed that can act both as displays, and hence information transmitters, and light-converting devices such as light sensors or light-harvesting devices. Cho et al., U.S. 2021/0036060 (published Feb. 2, 2021), for example, describes a color-filter based display device having a light-emitting layer on a surface of a substrate, and sensing elements disposed on a substrate attached to the other surface for imaging applications. As another example, Chinese Pat. No. CN102983154B (Ping et al., issued Oct. 21, 2015) discloses an image receiving and transmitting device with a transparent organic light-emitting diode (OLED) display on a substrate integrating silicon-based photodiodes.

U.S. 2017/0005235 (Chou et al., published Jan. 5, 2017) further expands the range of functionalities that can be added to a display by disclosing light-emitting diodes (LEDs) that can be operated both as high-efficiency emitting devices and high efficiency photodetectors and photovoltaic devices. This means that a device containing arrays of such an LED can be used as a display in an LED operation mode, a camera in a photodetector and imaging mode, and power supply in a photovoltaic device mode. Another example of a display device with integrated power supply functionality is U.S. 2007/0089784 (No et al., published Apr. 26, 2007), which discloses a solar cell-driven display device including a dye-sensitized solar cell. The solar cell-driven display device exhibits the display device function using only solar light, without the need for a separate external power supply.

As in the case of QLEDs, crosslinkable materials also have been integrated into light-converting materials, especially in organic solar cells and organic photodectors. The basic architecture for both organic solar cells and organic photodectors includes an organic photo-active layer (PAL), which is sandwitched between an anode acting as a hole collection electrode, and a cathode acting as an electron collection electrode. At least one of the electrodes must be semi-transparent to allow an external light stimulus to reach the PAL to excite the PAL to generate free charge carriers. As reported by Ruhme & McCulloch Organic photovoltaics: Crosslinking for optimal morphology and stability Materials Today, 2015, 8, 425 and by Zhong et al. High-Detectivity Non-Fullerene Organic Photodetectors Enabled by a Cross-Linkable Electron Blocking Layer ACS Applied Materials and Intefaces, 2020, 12, 45092, crosslinkable materials have been integrated in both organic solar cells and organic photodectors with the aim of improving the stability and morphology of of crosslinked PAL and/or charge blocking layers, with advantageous effects on the device performance.

### SUMMARY OF INVENTION

None of the disclosures in the prior art demonstrates a strategy to fabricate an array of solution processed devices with different functionalities, whereby the architecture and composition of each device in the array can be selectively optimized by leveraging the photo-crosslinking platform. The present application describes a multifunction display device structure having a sub-pixel array configuration for use in a multicolor and multifunction high-resolution display. The sub-pixel array configuration has optoelectronic devices including both light-emitting devices and light-converting devices (such as solar cells and photodiodes), with each type of optoelectronic device occupying a fraction of the array in the overall sub-pixel arranged display device. In contrast to conventional multifunction combined emissive and light-converting devices, in the present application the sub-pixel arrangement is obtained on the same outer surface of the substrate via photo-lithographic patterning of one or more solution-processed photo-crosslinkable materials. The direct photo-crosslinking of such materials embedded in the device structure enables patterning and the fabrication of optoelectronic devices serving different functionalities, and also facilitates the selective optimization of these devices. Each sub-pixel of the array may differ from other sub-pixels in the array based on the type of materials embedded in the sub-pixel, number of layers, layer thickness and overall thickness, and shape and area. Such parameters may be tuned depending on the functionality served by a given sub-pixel.

In an exemplary embodiment, the multifunction display device includes an array of optoelectronic devices positioned in a sub-pixel arrangement on a substrate, including at least one light-emitting device and at least one light-converting device such as a solar cell or photodiode, with each optoelectronic device including a bottom electrode, a top electrode, at least one solution processable semiconductor, and at least one photo-crosslinkable material between the electrodes. The sub-pixel arrangement may be positioned within a bank structure on a substrate, wherein the bank structure includes banks made of an insulating material that separate adjacent optoelectronic devices of different sub-pixels.

The light-emitting devices included in the sub-pixel array may be configured as QLEDs, and thus with QDs acting as the active electroluminescent material in the emissive layer. This use of QDs as the emissive material has the advantages offered by the QLED technology described above, including the ability to fabricate the QLEDs with improved performance in a sub-pixel arrangement by using the CCTEL method described in U.S. Pat. No. 10,581,007 referenced above. The photo-active layer of an organic or hybrid organic-inorganic solar cell or photodetector, deposited from solution or liquid dispersion, may be patterned and integrated in the sub-pixel arrangement with the light-emitting devices via photo-lithography. Similarly to the CCTEL used for QLEDs for light emission, patterned light-converting devices also may be obtained by including a photo-crosslinkable material incorporated into the photo-active layer for light conversion.

In another exemplary embodiment, a multifunction display device including an array of optoelectronic devices with a sub-pixel arrangement in a banked substrate may be formed by depositing one or more photo-crosslinkable materials between the top electrode and the active layer (i.e. emissive or photo-active layer, respectively) to form a capping layer. After photo-crosslinking, the capping layer effectively seals the active layer in the banked sub-pixel exposed to the light stimulus, thereby enabling the deposition of different active layers in different sub-pixels of the banked substrate. Such formation follows an iterative process including the following steps: (i) active layer deposition, (ii) photo-crosslinkable capping layer deposition, (iii) photo-crosslinking of the capping layer for a fraction of the sub-pixel on the substrate, and (iv) washing or development to remove both the active layer and the capping materials from the areas not to be exposed to the light stimulus.

Accordingly, a sub-pixel array device includes a plurality of optoelectronic devices disposed on a substrate, the plurality of optoelectronic devices including a light-emitting device and a light-converting device, and a bank structure that separates adjacent optoelectronic devices of the plurality of optoelectronic devices. Each of the plurality of optoelectronic devices comprises a first electrode, a second electrode, an active layer disposed between the first electrode and the second electrode and including a solution processable semiconductor, and a photo-crosslinkable material disposed between the first electrode and the second electrode. The photo-crosslinkable material may be incorporated within the active layer of each of the plurality of optoelectronic devices, so as to form a light-emitting device having a photo-crosslinkable emissive layer and a light-converting device having a photo-crosslinkable photo-active layer. The photo-crosslinkable material may be disposed between the active layer and the second electrode, such as incorporated within a capping layer or a charge transport layer disposed between the active layer and the second electrode

To the accomplishment of the foregoing and related ends, the invention, then, comprises the features hereinafter fully described and particularly pointed out in the claims. The following description and the annexed drawings set forth in detail certain illustrative embodiments of the invention. These embodiments are indicative, however, of but a few of the various ways in which the principles of the invention may be employed. Other objects, advantages and novel features of the invention will become apparent from the following detailed description of the invention when considered in conjunction with the drawings.

### BRIEF DESCRIPTION OF DRAWINGS

FIG. 1A and FIG. 1B are schematic cross-sectional views of a pixel with two patterned sub-pixels with photo-crosslinked active layers including an emissive layer and a light-converting layer.

FIG. 2A, FIG. 2B, FIG. 2C, and FIG. 2D are schematic cross-sectional views of exemplary photo-crosslinkable active layers of a sub-pixel arranged device, including an emissive layer and a light-converting layer before and after photo-crosslinking.

FIG. 3A, FIG. 3B, FIG. 3C, and FIG. 3D are energy band diagrams of exemplary photo-crosslinked light-emitting and light-converting devices of a sub-pixel-arranged device.

FIG. 4 is a schematic cross-sectional view of a patterned pixel arrangement of sub-pixels of a sub-pixel arranged device with a photo-crosslinked capping layer on top of the active layers including an emissive layer and a light-converting layer.

FIG. 5 is a schematic cross-sectional view of a patterned pixel arrangement of sub-pixels of a sub-pixel arranged device with a combined photo-crosslinked capping and charge transporting layer on top of the active layers including an emissive layer and a light-converting layer.

FIG. 6A, FIG. 6B, and FIG. 6C are schematic cross-sectional views of a pixel having a sub-pixel arrangement with photo-crosslinked red, green, and blue emissive sub-pixels, and a photo-crosslinked light-converting sub-pixel.

FIG. 7 is a schematic cross-sectional top view of a pixel having a sub-pixel arrangement with photo-crosslinked red, green, and blue emissive sub-pixels, and a photo-crosslinked light-converting sub-pixel.

### DESCRIPTION OF EMBODIMENTS

The present application relates to an array of optoelectronic devices on the same surface of a substrate including at least one light-emitting device, such as a QLED, and at least one light-converting device such as a light-harvesting device (i.e., solar cell) or light-sensing device (i.e., photodiode or photodetector). Such an array of optoelectronic devices may be integrated as a pixel in a matrix of pixels to form a multifunction display device that can both emit light and convert light. As a result, at least a fraction of the pixels in such a display may include a sub-pixel arrangement of one or more QLEDs combined with a light-converting device. An array of optoelectronic devices on the same outer surface of a substrate may be obtained by photo-lithographic patterning of one or more solution-processed semiconductors and cross-linkable materials.

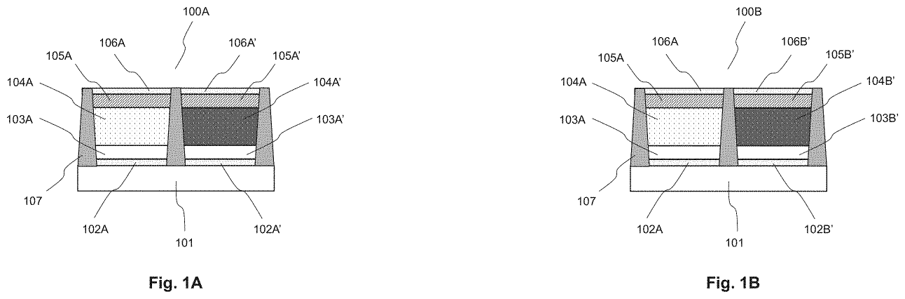

FIGS. 1A-1B are schematic cross-sectional views of a pixel 100A/100B in an exemplary sub-pixel-arranged device. Each pixel 100A and 100B includes one or more sub-pixels with a quantum dot (QD) light-emitting device (QLED), and one or more sub-pixels with a light-converting device (one light-emitting device and one light-converting device are depicted in these examples). As used herein, a light-converting device is an optoelectronic device having a photo-active layer that responds to a light stimulus. Light-converting devices include, for example, light-sensing devices such as photodiodes and photodectors, and light-harvesting devices such as solar cells.

As illustrated in FIGS. 1A and 1B, an exemplary light-emitting device (QLED) included as a sub-pixel in the pixel-arranged devices 100A and 100B includes multiple planar layers disposed on a substrate 101. The multiple planar layers of the light-emitting device include: a first or bottom electrode 102A; a second or top electrode 106A; an emissive layer (EML) 104A containing QDs and disposed between the first electrode 102A and the second electrode 106A; one or more optional charge transport layers (CTL) 103A disposed between the first electrode 102A and the EML 104A; and one or more optional second CTLs 105A disposed between the second electrode 106A and the EML 104A. A QLED may be characterized as “bottom-emitting” if light is primarily emitted out of the substrate 101 side, and a QLED may be characterized as “top-emitting” if light is primarily emitted out of the second electrode 106A side opposite from the substrate 101. Similarly, a QLED may be characterized as bottom emitting if the first (bottom) electrode 102A is semitransparent so as to transmit light, and may be characterized as top emitting if the second (top) electrode 106A is semitransparent so as to transmit light. For a bottom emitting QLED, the substrate 101 also is semitransparent or transparent so as to emit light.

The pixel-arranged devices 100A and 100B also each include a light-converting sub-pixel. The pixel 100A differs from pixel 100B is that in the pixel 100A the light-converting sub-pixel is configured as a light-sensing device such as a photodiode, and in the pixel 100B the light-converting sub-pixel is configured as a light-harvesting device such as a solar cell. Otherwise, the light-converting sub-pixels of pixels 100A and 100B have a comparable structure. Accordingly, an exemplary photodiode (solar cell) included as a sub-pixel in the pixel-arranged device 100A (100B) includes multiple planar layers disposed on the substrate 101, including: a first or bottom electrode 102A′ (102B′); a second or top electrode 106A′ (106B′); a photo-active layer 104A′ (104B′) disposed between the first electrode 102A′ (102B′) and the second electrode 106A′ (106B′); one or more optional charge transport layers (CTL) 103A′ (103B′) disposed between the first electrode 102A′ (102B′) and the photo-active layer 104A′ (104B′); and one or more optional second CTLs 105A′ (105B′) disposed between the second electrode 106A′ (106B′) and the photo-active layer 104A′ (104B′). The photodiode photo-active layer 104A′ and the solar cell photo-active layer 104B′ each may include a combination of at least of two semiconductors corresponding to an electron donor semiconductor and an electron acceptor semiconductor with different energy-gaps and frontier energy levels that favor the formation of free charge carriers upon light excitation. In exemplary embodiments, at least one of the semiconductors in the photo-active layers 104A′ and 104B′ may be an organic semiconductor to give a so-called “organic photodetector” or “organic solar cell”, or a hybrid organic-inorganic photodector/solar cell. Optionally, the photo-active layers 104A′ and 104B′ may contain QDs as the semiconductors.

To enable patterning, and hence the formation of the emissive layer 104A and photo-active layer 104A′/104B′ on different areas of the substrate within a given pixel, both such emissive and photo-active layers may be deposited from a solution or dispersion containing at least one photo-cross-linkable material. Further details of the structure and composition of such emissive layer and photo-active layer are described below.

A QLED with what is commonly known as a “conventional structure” has a structure in which the first electrode 102A is an anode, the second electrode 106A is a cathode, the one or more optional first CTLs 103A are hole transport layers (HTL), and the one or more optional second CTLs 105A are electron transport layers (ETL). Such a QLED configuration also is referred to in the art as a “standard structure”, “direct structure”, or “regular structure”. Likewise, a light-converting device with a “conventional structure” has a structure in which the first electrode 102A′ (102B′) is an anode, the second electrode 106A′ (106B′) is a cathode, the one or more optional first CTLs 103A′ (103B′) are hole transport layers (HTL), and the one or more optional second CTLs 105A′ (105B′) are electron transport layers (ETL). A QLED or light-harvesting device with what is commonly known as an “inverted structure” has a structure in which the first electrode 102A (102A′, 102B′) is a cathode, the second electrode 106A (106A′, 106B′) is an anode, the one or more optional first CTLs 103A (103A′, 103B′) are ETLs, and the one or more optional second CTLs 105A (105A′, 105B′) are HTLs. One or more of the HTLs or ETLs in both the QLED and light-converting sub-pixel structures may act, concurrently, as a charge blocking layer (CBLs) as to the non-transport charge, i.e., an HTL electron blocking layer or ETL hole blocking layer. Although such layers acting as CBLs are optional, when present the CBLs operate to enhance the device performance, especially in photodiodes in which CBLs limit the undesired dark currents flowing through the device.

The substrate 101 may have any suitable shape and size, and may include one or more materials typically used in light-emitting devices, such as glass and polymers, including polyimides, polyethenes, polyethylenes, polyesters, polycarbonates, polyethersulfones, polypropylenes, and/or polyether ether ketones.

The first electrodes 102A, 102A′, 102B′ and second electrodes 106A, 106A′, 106B′ may include one or more materials typically used in QLEDs and light-converting devices. At least one of the electrodes is a transparent or semi-transparent electrode for QLED light emission and light stimulus, and the other of the electrodes is a reflective electrode. In the case of a bottom-emitting QLED, the first electrode 102A will be transparent or semi-transparent. Typical materials for the transparent or semi-transparent electrode include tin-doped indium oxide (ITO), fluorine-doped tin oxide (FTO), indium-doped zinc oxide (IZO), aluminum-doped zinc-oxide (AZO), indium-doped cadmium-oxide, and the like. In the case of a top-emitting QLED, the first electrode 102A may be made of any suitable reflective metal such as silver. In bottom-emitting devices, the second electrode 106A is a reflective electrode. Typical materials used for the reflective electrode in a bottom emitting device include metals such as aluminium or silver (cathodes for a conventional structure) and gold or platinum (anodes for an inverted structure). Top-emitting QLEDs will use a semi-transparent second or top electrode 106A such as thin (<20 nm) silver, a metallic bilayer (e.g. 2 nm Aluminium/15 nm Silver), magnesium-silver alloys, silver nanowires, graphene, or composite combinations thereof. The first electrodes 102A, 102A′, 102B′ and second electrodes 106A, 106A′, 106B′ may be provided in any suitable arrangement. One or more adjacent optoelectronic devices in the sub-pixel arranged device may share one or more a common electrodes, or electrodes may be different for each sub-pixel. In another embodiment, either the first (bottom) or second (top) electrode may be common to at least two (up to all) sub-pixels in the array, with the other electrode being different or patterned for each sub-pixel in the array. In addition, the first electrodes 102A, 102A′, 102B′ and second electrodes 106A, 106A′, 106B′ may be addressed by a thin-film transistor (TFT) circuit.

Each optoelectronic device (QLED, photodiode, or solar cell) occupying a sub-pixel of the sub-pixel-arranged device may be separated at least in part from an adjacent optoelectronic device in the array by one or more insulating materials that form a bank structure 107. Such a bank structure 107, as depicted in FIGS. 1A and 1B, defines wells that may include the first electrodes 102A, 102A′ and 102B′. The top or second electrodes 106A, 106A′ and 106B′ electrodes also may be included in the wells or may extend beyond the wells. Suitable insulating materials for the bank structure may include, but are not limited to, polyimides.

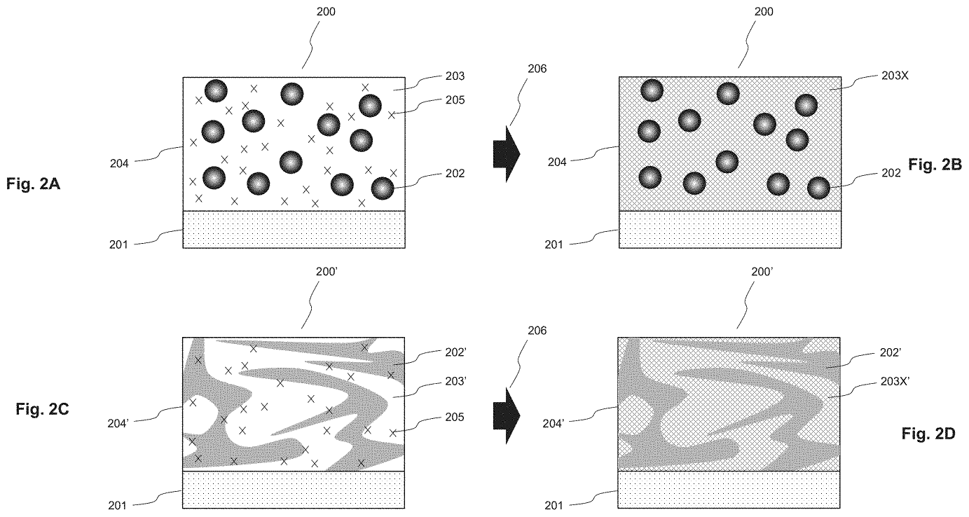

In the example of FIGS. 1A and 1B, the active layers 104A/104A′/104B′ each includes a crosslinkable material incorporated as part of said active layers. FIGS. 2A-2D are schematic cross-sectional views of exemplary photo-crosslinkable active layers, including an exemplary emissive layer and an exemplary light-converting layer of a sub-pixel arranged device, before and after photo-crosslinking. The illustrated crosslinkable emissive layer or crosslinkable light-converting layer may be employed respectively as one of the corresponding active layers 104 of FIGS. 1A or 1B. In particular, FIGS. 2A and 2B relate to a light-emitting device structure, whereas FIGS. 2C and 2D relate to a light-converting device structure such as a photodiode or light-harvesting device, which may be deposited on a generic underlayer such as a charge transport layer or an electrode.

As shown in FIG. 2A, an exemplary light-emitting device component 200 includes a combined charge transport and emissive layer (CCTEL) 204 deposited on an underlayer 201, the underlayer being one of a charge transport layer or an electrode layer such as depicted in FIGS. 1A and 1B. The CCTEL 204 includes a blend of QDs 202 dispersed within a photo-crosslinkable charge transport matrix 203, and thus the CCTEL 204 combines charge transport properties of a CTL and light-emitting properties of an EML. The QDs 202 may include colloidal semiconductor nanocrystals that operate as quantum dots covered by surface ligands, which enable the dispersion of the QDs in conventional solvents and passivate crystal defects present on the surface of the QDs. The nanocrystals may include one or multiple co-crystallized shells of different semiconducting materials to form so-called core-shell QDs. Furthermore, in FIGS. 2A and 2B the QDs 202 are depicted as spherical, although the QDs also could exhibit an elongated shape (rod-like, platelet-like, discoidal) or shapes of higher complexity (quasi-spherical core with multi-branched shell) as are known in the art. Moreover, the shell materials may not cover the core evenly, and the thickness of the shell may not be uniform, with a corresponding shell volume lower, equal to, or higher than the core volume.

Exemplary quantum dot core and shell materials may include one or more of: InP, carbon, CdSe, CdS, CdSeₓS₁₋ₓ, CdTe, CdₓZn₁₋ₓSe, CdₓZn₁₋ₓSe_{y}S_{1-y}, ZnSe, ZnS, ZnSₓTe₁₋ₓ, ZnSeₓTe₁₋ₓ, Zn_{w}Cu_{z}In_{1-(w+z)}S where 0≤w, x, y, z≤1. In some embodiments, w, x, y, z may vary within the core and/or shell volume. Core and shell materials also may include perovskite-like and double-perovskite structures with ABX₃, A₂BB′X₆, ABX₄, A₃B₂X₉ stoichiometry. Exemplary ligands include alkyl, -alkenyl, -alkynyl or aryl (linear, branched or cyclic) thiols with 1 to 30 atoms of carbon; alkyl, -alkenyl, -alkynyl or aryl (linear, branched or cyclic) alcohols with 1 to 30 atoms of carbon; alkyl, -alkenyl, -alkynyl or aryl (linear, branched or cyclic) carboxylic acids with 1 to 30 atoms of carbon; tri-alkyl, -alkenyl, -alkynyl or aryl (linear, branched or cyclic) phosphine oxides with 1 to 60 atoms of carbon; alkyl, -alkenyl, -alkynyl or aryl (linear, branched or cyclic) amines with 1 to 30 atoms of carbon; salts formed from any of the above listed compounds (the anion or the cation are the binding moieties); halogen salts (the anion or the cation are the binding moieties).

An average distance between QDs may not be uniform, and clusters of QDs may form in the CCTEL. The QDs may also segregate towards one of the outer surfaces of the CCTEL. The CCTEL mixture 204 may be deposited via commonly used solution process techniques, including drop casting, spin coating, slot die coating, doctor blading, spray coating, dip coating, bar coating, and inkjet printing.

FIG. 2A shows an initial state of the CCTEL 204 upon deposition onto the underlayer 201, which subsequent to deposition may be treated by a photo-crosslinking or photo-polymerization process 206 using light stimulation as is known in the art. FIG. 2B shows the resultant structure of the CCTEL 204 after performing the photo-crosslinking or photo-polymerization process 206. By blending the QDs 202 in the photo-crosslinkable matrix 203 to form the CCTEL 204, patterning via the photo-crosslinking or photo-polymerization process 206 of the CCTEL can be obtained, following the protocol of Angioni et al. in U.S. Pat. No. 10,581,007 referenced above. In this way, the CCTEL 204 can be deposited on selected areas of any underlayer 201, and thereby any selected areas of the substrate 101 onto which the arrays of devices 100A and 100B are fabricated as shown in FIGS. 1A and 1B. The result of the photo-crosslinking or photo-polymerization process 206 is to alter the photo-crosslinkable charge transport matrix 203 from its initial state shown in FIG. 2A into a crosslinked charge transport matrix 203X as shown in FIG. 2B.

An average distance between QDs 202 and QD distribution in the crosslinked matrix 203X may be the same as in initial state of the non-crosslinked matrix 203, i.e. in the matrix prior to the photo-crosslinking or photo-polymerization 206. Alternatively, the initial average distance between QDs and QD distribution in the CCTEL 204 may vary following the photo-crosslinking or photo-polymerization process 206. Furthermore, the QDs in FIG. 2A and 2B are depicted as being homogeneously distributed within the entire volume of the CCTEL 204. However, crosslinking may also cause phase segregation from the crosslinkable materials 203 of QDs 202 toward a portion of the CCTEL 204 either closest to or farthest from the underlayer 201.

Exemplary charge-transporting and photo-crosslinkable materials 203/203X may be N4,N4′-Bis(4-(6-((3-ethyloxetan-3-yl)methoxy)hexyl)phenyl)-N4,N4′-diphenylbiphenyl-4,4′-diamine (OTPD); N4,N4′-Bis(4-(6-((3-ethyloxetan-3-yl)methoxy)hexyloxy)phenyl)-N4,N4′-bis(4-methoxyphenyl)biphenyl-4,4′-diamine (QUPD); N,N′-(4,4′-(Cyclohexane-1,1-diyl)bis(4,1-phenylene))bis(N-(4-(6-(2-ethyloxetan-2-yloxy)hexyl)phenyl)-3,4,5-trifluoroaniline) (X-F6-TAPC); N4,N4′-Di(naphthalen-1-yl)-N4,N4′-bis(4-vinylphenyl)biphenyl-4,4′-diamine (VNPB); 9,9-Bis[4-[(4-ethenylphenyl)methoxy]phenyl]-N2,N7-di-1-naphthalenyl-N2,N7-diphenyl-9H-Fluorene-2,7-diamine (VB-FNPD); 3,5-di-9H-carbazol-9-yl-N,N-bis[4-[[6-[(3-ethyl-3-oxetanyl)methoxy]hexyl]oxy]phenyl]benzenamine (Oxe-DCDPA). Other photo-crosslinkable and charge-transport materials 203/203X that may be incorporated in the CCTEL more generally may include any class of organic semiconductors with photo-crosslinkable moieties, including oxetane, epoxy, bromo, vinyl, acrylate and and azide functional groups. The same moieties may be present as functional groups of the QD ligands, thereby eneabling direct crosslinking of the QDs 202 with the crosslinkable matrix 203.

The CCTEL 204 further may include photo-initiators 205 that are dispersed within the photo-crosslinkable charge transport matrix 203 to facilitate the photo-cross-linking or photo-polymerisation process 206. The relative content of the photo-initiators 205 inside the CCTEL mixture may vary from 0.1 to 20 wt %. Exemplary photo-initiators include sulfonium- and iodonium-salts (e.g. triphenylsulfonium triflate, diphenyliodonium triflate, iodonium, [4-(octyloxy)phenyl]phenyl hexafluorophosphate, bis(4-methylphenyl)iodonium hexafluorophosphate, diphenyliodonium hexafluoroarsenate, diphenyliodonium hexafluoroantimonate, etc), chromophores containing the benzoyl group (benzoin ether derivatives, halogenated ketones, dialkoxyacetophenones, diphenylacetophenones, etc), hydroxy alkyl heterocyclic or conjugated ketones, benzophenone- and thioxanthone-moiety-based cleavable systems (such as benzophenone phenyl sulfides, ketosulfoxides, etc), benzoyl phosphine oxide derivatives, phosphine oxide derivatives, trichloromethyl triazines, biradical-generating ketones, peroxides, diketones, azides and aromatic bis-azides, azo derivatives, disulfide derivatives, disilane derivatives, diselenide and diphenylditelluride derivatives, digermane and distannane derivatives, peresters, barton's ester derivatives, hydroxamic and thiohydroxamic acids and esters, organoborates, titanocenes, chromium complexes, aluminate complexes, tempo-based alkoxyamines, oxyamines, alkoxyamines, and silyloxyamines.

As shown in FIGS. 2C and 2D, a comparable crosslinking process may be applied to a crosslinkable light-converting device such as a photodiode or light-harvesting device such as a solar cell. As shown in FIG. 2C, a light-converting device component 200′ includes a photo-active layer (PAL) 204′ deposited on an underlayer 201, which again may be one of a charge transport layer or an electrode layer such as depicted in FIGS. 1A and 1B. Accordingly, a protocol similar to that for the CCTEL 204 in the QLED sub-pixel of the device array may be adapted to pattern the PAL 204′ of the light-converting device, and thus the PAL may be disposed on selected areas of any underlayer 201. As with the CCTEL 204, the underlayer 201 on which the PAL 204′ is deposited also could be a charge transport layer or an electrode. As shown in FIG. 2C, the PAL 204′, such as for example as employed in an organic photodiode or solar cell, includes a blend of at least two semiconductors including a first semiconductor 202′ and a second semiconductor 203′, wherein second semiconductor 203′ is a photo-crosslinkable material. Similar crosslinkable materials may be employed in the PAL 204′ as in the CCTEL 204. For example, suitable photo-crosslinkable materials for the PAL 204′ may include organic semiconductors with photo-crosslinkable moieties, including oxetane, epoxy, bromo, vinyl, acrylate and and azide functional groups. Depending on the nature of the photo-chemical process involved in the crosslinking, the PAL also may contain photo-initiators 205. Exemplary photo-initiators 205 of the PAL may include the same materials as suitable for CCTEL photo-crosslinking referenced above.

Accordingly, FIG. 2C shows an initial state of the PAL 204′ upon deposition onto the underlayer 201, which subsequent to deposition may be treated by a photo-crosslinking or photo-polymerization process 206 using light stimulation as is known in the art. FIG. 2D shows the resultant structure of the PAL 204′ after performing the photo-crosslinking or photo-polymerization process 206. By blending the first semiconductor 202′ and the crosslinkable second semiconductor 203′, similarly as above patterning via the photo-crosslinking or photo-polymerization process 206 of the PAL can be obtained following the protocol of Angioni et al. in U.S. Pat. No. 10,581,007 referenced above. In this way, the PAL 204′ can be deposited on selected areas of any underlayer 201, and thereby any selected areas of the substrate 101 onto which the arrays of devices 100A and 100B are fabricated as shown in FIGS. 1A and 1B. The result of the photo-crosslinking or photo-polymerization process 206 is to alter the photo-crosslinkable semiconductor material 203′ from its initial state shown in FIG. 2C into a crosslinked semiconductor material 203X′ as shown in FIG. 2D.

To enable efficient generation of free charges upon light stimulation to perform the photo-crosslinking process, semiconductors 202′ and 203′ in the PAL present staggered frontier energy levels, to form a so-called “bulk heterojunction”. The semiconductor with higher frontier energy levels is conventionally called the “electron donor”, whereas the semiconductor with lower frontier energy levels is conventionally called the “electron acceptor”. For an organic photodiode or organic solar cell electron donor, any suitable organic semiconductor, typically a polymer, may be employed. Exemplary electron acceptor materials may be fullerene derivatives or organic molecular compounds (small molecule or polymer) with suitably low frontier energy levels as compared to the electron donor semiconductor.

In an exemplary embodiment, both semiconductors 202′ and 203′ may contain crosslinkable functional groups and be photo-crosslinkable. In an alternative exemplary PAL, none of the semiconductors 202′ and 203′ forming the bulk-heterojunction may be photo-crosslinkable. In such a PAL, photo-crosslinkability may be obtained by adding a photo-crosslinkable additive to blend with the semiconductors, provided the photo-crosslinkable additive does not interfere with the optoelectronic properties of the light-converting device. Photo-crosslinking in the PAL may occur only in the second semiconductor as shown in FIGS. 2C and 2D, or the first semiconductor also may be photo-crosslinkable, or crosslinking reactions may occur also between moieties of different semiconductors. In another embodiment, the PAL 204′ may contain at least one material that also is present in the CCTEL 204. This could be the photo-crosslinkable matrix 203 of the CCTEL 204, which may act as the second photo-crosslinkable semiconductor 203′ in the PAL 204′, or the QDs 202, which may serve as the first semiconductor in the bulk-heterojunction forming the PAL 204′.

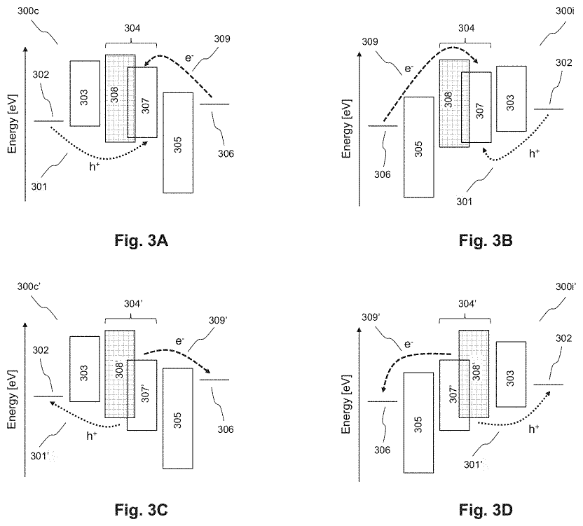

FIGS. 3A-3D are energy band diagrams of exemplary photo-crosslinked light-emitting and light-converting devices of a sub-pixel-arranged device. The structure and operation of the optoelectronic devices occupying the different sub-pixels of the array are illustrated by FIGS. 3A-3D, in which energy band diagrams 300c, 300i, 300c′, and 300i′ are shown.

FIGS. 3A and 3B show the exemplary energy band diagrams 300c and 300i of a light-emitting QLED with a “conventional” and an “inverted” structure, respectively, based on a CCTEL 304 containing emissive QDs with band diagram 307 and a photo-crosslinked matrix with band diagram 308. Left-most energy levels in FIGS. 3A and 3B correspond to the Fermi level of the first or bottom electrode 102A of FIGS. 1A and 1B, which is an anode with Fermi level 302 in a conventional structure (FIG. 3A), and a cathode with Fermi level 306 in an inverted structure (FIG. 3B). Right-most energy levels correspond to the cathode 306 (FIG. 3A) in a conventional QLED, and to the anode 302 (FIG. 3B) in an inverted QLED. The band diagram of the optional HTL 303 is represented between the CCTEL 304 and the anode 302, while the band diagram of the optional ETL 305 is represented between the CCTEL 304 and the cathode 306. The hole current 301 and the electron current 311 flowing through the light-emitting device, when subjected to a forward bias, are controlled by the hole and electron mobility of each component of the QLED structure, and by the energetic barriers at interfaces between the different layers.

FIGS. 3C and 3D show the exemplary energy band diagrams 300c′ and 300i′ of a light-converting device (e.g., photodiode or solar cell) with a “conventional” and an “inverted” structure, respectively, based on a PAL 304′ containing a first electron-acceptor semiconductor with band diagram 307′ and a second electron-donor semiconductor with band diagram 308′. Left-most energy levels in FIGS. 3C and 3D correspond to the Fermi level of the first or bottom electrode 102A′/102B′ of FIGS. 1A and 1B, which is an anode with Fermi level 302 in a conventional structure (FIG. 3C), and a cathode with Fermi level 306 in an inverted structure (FIG. 3D). Right-most energy levels correspond to the cathode 306 (FIG. 3C) in a conventional light-converting device to the anode 302 (FIG. 3D) in an inverted light-converting device. The band diagram of the optional HTL 303 is represented between the PAL and the anode 302, while the band diagram of the optional ETL 305 is represented between the PAL and the cathode 306. The photo-generated hole current 301′ and the photo-generated electron current 311′ flowing through the light-converting device, when the device is irradiated with light (and, for an exemplary photodiode, when subjected to a reverse bias) are controlled by the hole and electron mobility of each component of the light-converting device structure, and by the energetic barriers at interfaces between the different layers. As detailed above, the optional HTL/ETL may facilitate charge collection/extraction from the electrodes, and also may act as charge blocking layers that prevent charge injection from the same electrodes and thereby limit undesired dark currents.

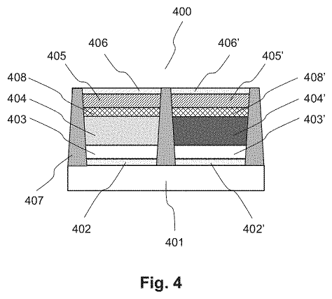

FIG. 4 is a schematic cross-sectional view of a patterned pixel arrangement 400 with a photo-crosslinked capping layer on top of the active layers including an emissive layer and a light-converting layer. As described above, in the embodiment of FIGS. 1-2 the cross-linkable material is incorporated into the active layers. The embodiment of FIG. 4 differs in that the active layers do not incorporate the crosslinkable material, but rather the crosslinkable material is incorporated into a separate capping layer disposed between the active layer and the second electrode. Each pixel 400 may include one or more sub-pixels with a light-emitting device such as a QLED, and one or more sub-pixels with a light-converting device such as a photodiode or light-harvesting device (e.g., solar cell).

An exemplary QLED included as a sub-pixel in the said pixel-arranged device 400 includes multiple planar layers disposed on a substrate 401, which include: a first or bottom electrode 402; a second or top electrode 406; an emissive layer (EML) containing QDs 404 disposed between the first electrode 402 and the second electrode 406; one or more optional first charge transport layers (CTLs) 403 disposed between the first electrode 402 and the EML 404; and one or more optional second CTLs 405 disposed between the second electrode 406 and the EML 404. At least one of the electrodes is semitransparent to enable the out-coupling of light generated in the EML.

Similarly, an exemplary light-converting device included as a sub-pixel in the pixel-arranged device 400 includes multiple planar layers disposed on the substrate 401, including: a first or bottom electrode 402′; a second or top electrode 406′; a photo-active layer (PAL) 404′ disposed between the first electrode 402′ and the second electrode 406′; one or more optional first CTLs 403′ disposed between the first electrode 402′ and the PAL 404′; and one or more optional second CTLs 405′ disposed between the second electrode 406′ and the PAL 404′. The PAL 404′, similarly to the previous embodiment, includes a combination of at least of two semiconductors (an electron-donor and an electron acceptor semiconductor) with different energy-gaps and frontier energy levels that favor the formation of free charge carriers upon light excitation. In an exemplary embodiment, at least one of the semiconductors in the PAL 404′ may be an organic semiconductor, for example to form an organic photodetector or organic solar cell, or a hybrid organic-inorganic photodector/solar cell. Optionally, the PAL 404′ may contain QDs as semiconductors.

Similarly as in the previous embodiment, each optoelectronic (light-emitting or light-converting) device occupying a sub-pixel of the sub-pixel-arranged device 400 may be separated at least in part from an adjacent optoelectronic device in the array by one or more insulating materials to form a bank structure 407.

As referenced above, in the embodiment of FIGS. 1 and 2 the EML and PAL contain at least one photo-crosslinkable material, and, therefore, can be directly photo-crosslinked. In the embodiment of the pixel arranged device 400 of FIG. 4, the EML and PAL do not include a photo-crosslinkable material, and instead one or more photo-crosslinkable capping layers 408 and 408′ are deposited from solution between the active layers EML 404 and PAL 404′ and the second or top electrode 406. Such a capping layer 408 and 408′, after photo-crosslinking, effectively seals the corresponding active layer in the sub-pixel exposed to the light stimulus, thereby enabling the deposition of different active layers in different sub-pixels of the banked substrate. The deposition of different active layers may follow an iterative process including the following steps: (i) active layer deposition on an underlayer such as a CTL or an electrode, (ii) photo-crosslinkable capping layer deposition on the active layer, (iii) photo-crosslinking of the capping layer in the desired sub-pixel, and (iv) washing or development to remove both the active layer and the capping materials from the sub-pixels not exposed to the light stimulus.

Suitable materials for the photo-crosslinked capping layers 408 and 408′ include solution processable materials that contain photo-crosslinkable moieties, including oxetane, epoxy, bromo, vinyl, acrylate and and azide functional groups. Photo-crosslinked layers 408 and 408′ also may contain photo-initiators belonging to the classes of compounds referenced above as to photo-initiator 205.

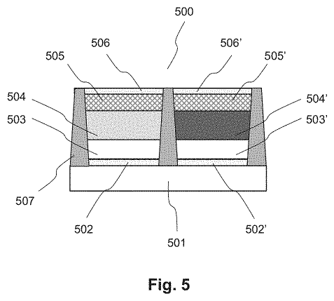

FIG. 5 is a schematic cross-sectional view of a patterned pixel arrangement 500 of sub-pixels with a combined photo-crosslinked capping and charge transporting layer on top of the active layers including an emissive layer and a light-converting layer. As described above, in the embodiment of FIGS. 1-2 the cross-linkable material is incorporated into the active layers, and in the embodiment of FIG. 4 the crosslinkable material is incorporated into separate capping layers disposed on the active layers. The embodiment of FIG. 5 differs in that the crosslinkable material is incorporated within a charge transport layer (CTL) disposed between the active layer and the second or top electrode to act as a combined CTL and capping layer. Each pixel 500 may include one or more sub-pixels with a light-emitting device such as a QLED, and one or more sub-pixels with a light-converting device such as a photodiode or light-harvesting device (e.g., solar cell).

Each optoelectronic device of a sub-pixel of pixel 500 has a structure similar to that of one of sub-pixels in pixel 400 of FIG. 4. An exemplary QLED included as a sub-pixel in the said pixel-arranged device 500 includes multiple planar layers disposed on a substrate 501, which include: a first or bottom electrode 502; a second or top electrode 506; an emissive layer (EML) containing QDs 504 disposed between the first electrode 502 and the second electrode 506; one or more optional first charge transport layers (CTLs) 503 disposed between the first electrode 502 and the EML 404; and one or more second CTLs 505 disposed between the second electrode 506 and the EML 504. At least one of the electrodes is semitransparent to enable the out-coupling of light generated in the EML. Similarly, an exemplary light-converting device included as a sub-pixel in the pixel-arranged device 500 includes multiple planar layers disposed on the substrate 501, including: a first or bottom electrode 502′; a second or top electrode 506′; a photo-active layer (PAL) 504′ disposed between the first electrode 502′ and the second electrode 506′; one or more optional first CTLs 503′ disposed between the first electrode 502′ and the PAL 504′; and one or more second CTLs 505′ disposed between the second electrode 506′ and the PAL 504′.

In contrast to previous embodiments, in pixel 500 the cross-linkable capping layers and the second CTLs are combined to form combined photo-crosslinkable and charge transport layers 505 and 505′ disposed between the active layer (EML 504 or PAL 504′) and the second electrodes 506 and 506′. Crosslinkable CTLs 505 and 505′ may be composite layers including a blend of different materials, where at least one of such materials is photo-crosslinkable and at least one is conductive for charge transport. Alternatively, CTLs 505 and 505′ may contain a single photo-crosslinkable and charge transport material, serving both as the charge transport and crosslinked capping material for the underlying layers. Suitable materials for photo-crosslinked CTLs 505 and 505′ include solution processable materials that contain photo-crosslinkable moieties, including oxetane, epoxy, bromo, vinyl, acrylate and and azide functional groups. The photo-crosslinked CTLs 505 and 505′ also may contain photo-initiators belonging to the classes of compounds referenced above as to photo-initiator 205.

The above embodiments may be incorporated into a multifunction display device for light emission and light converting, formed via photo-lithographic patterning of one or more solution-processed semiconductors and photo-crosslinkable materials. Such a multifunction display device includes an array of optoelectronic devices that are arranged in a sub-pixel configuration of optoelectronic devices to form pixels of a multicolor and high-resolution display. For the integration of the disclosed optoelectronic devices into an exemplary multicolor and multifunction high-resolution display based on a matrix of pixels with said sub-pixel arrangement, each multifunction pixel includes at least four sub-pixels containing four different optoelectronic devices. One sub-pixel includes a light-converting device as the optoelectronic device (e.g., a light sensor such as a photodiode, or a light-harvesting device such as a solar cell), while each of the remaining three sub-pixels includes a light-emitting device having an emissive material that emits light of a different color as the optoelectronic device, such as for example QLEDs with an emissive layer having an emissive material that emits monochromatic red (R), green (G), or blue (B) light.

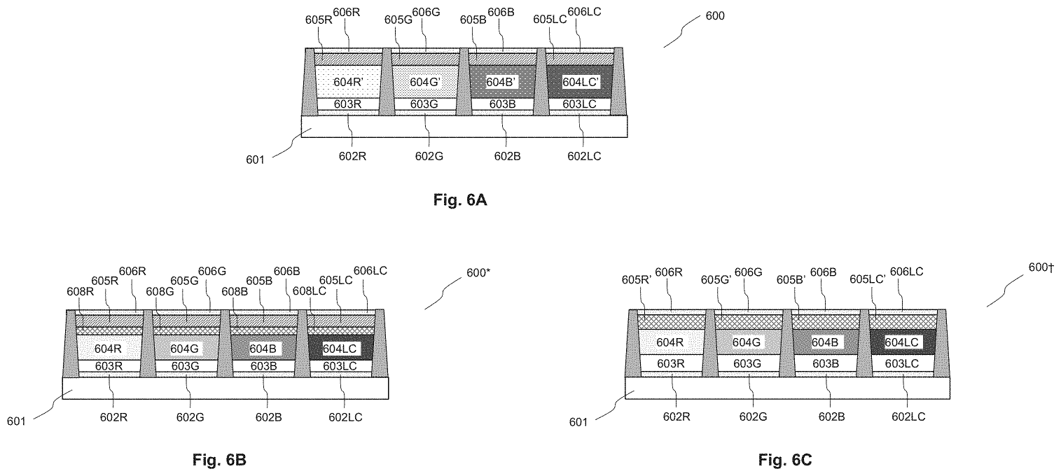

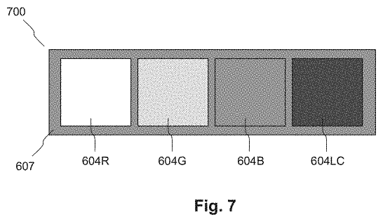

FIGS. 6A-6C are schematic cross-sectional views of pixels 600/600*/600† with photo-crosslinked red, green, and blue emissive sub-pixels, and a photo-crosslinked light-converting subpixel. FIG. 7 is a schematic top view of a pixel 700 with photo-crosslinked red, green and blue emissive sub-pixels, and a photo-crosslinked light-converting subpixel. In these depictions, reference numerals are further identified with the notation R, G, B, and LC to indicate respectively a red sub-pixel, green-sub-pixel, blue sub-pixel, and light-converting sub-pixel.

FIG. 6A depicts a pixel 600 that employs a sub-pixel arrangement comparably as in the embodiment of FIGS. 1A and 1B, in which the crosslinkable material is incorporated into the active layer, such as in the R/G/B emissive layer and the LC photo-active layer. In particular, an exemplary pixel 600 includes as sub-pixels multiple planar layers disposed on a substrate 601. The multiple planar layers include: a first or bottom electrode 602 R/G/B/LC; a second or top electrode 606 R/G/B/LC; a combined cross-linkable and active layer (emissive or light-converting layer) 604′ R/G/B/LC disposed between the first electrode 602 and the second electrode 606; one or more optional charge transport layers (CTL) 603 R/G/B/LC disposed between the first electrode 602 and the active layer 604; and one or more optional second CTLs 605 R/G/B/LC disposed between the second electrode 606 and the active layer 604. Each sub-pixel is separated from an adjacent sub-pixel by a bank structure 607, which further is depicted in the top view of FIG. 7. One of the electrodes is semitransparent for the outcoupling of light from the R/G/B emissive active layers.

FIG. 6B depicts an exemplary pixel 600* that employs a sub-pixel arrangement comparably as in the embodiment of FIG. 4, in which the crosslinkable material is incorporated into a separate capping layer disposed between the active layer, such as the R/G/B emissive layer or the LC photo-active layer, and the second or top electrode. In particular, an exemplary pixel 600′ includes as sub-pixels multiple planar layers disposed on a substrate 601. The multiple planar layers include: a first or bottom electrode 602 R/G/B/LC; a second or top electrode 606 R/G/B/LC; an active layer (emissive or light-converting layer) 604 R/G/B/LC disposed between the first electrode 602 and the second electrode 606; one or more optional charge transport layers (CTL) 603 R/G/B/LC disposed between the first electrode 602 and the active layer 604; one or more optional second CTLs 605 R/G/B/LC disposed between the second electrode 606 and the active layer 604; and a crosslinkable capping layer 608 R/G/B/LC disposed between the active layer 604 and the second or top electrode 606. Each sub-pixel is separated from an adjacent sub-pixel by a bank structure 607, which further is depicted in the top view of FIG. 7. Again, one of the electrodes is semitransparent for the outcoupling of light from the R/G/B emissive active layers.

FIG. 6C depicts an exemplary pixel 600† that employs a sub-pixel arrangement comparably as in the embodiment of FIG. 5, in which the crosslinkable material is incorporated into a charge transport layer disposed between the active layer, such as the R/G/B emissive layer and the LC photo-active layer, and the second or top electrode. In particular, an exemplary pixel 600t includes as sub-pixels multiple planar layers disposed on a substrate 601. The multiple planar layers include: a first or bottom electrode 602 R/G/B/LC; a second or top electrode 606 R/G/B/LC; an active layer (emissive or light-converting layer) 604 R/G/B/LC disposed between the first electrode 602 and the second electrode 606; one or more optional charge transport layers (CTL) 603 R/G/B/LC disposed between the first electrode 602 and the active layer 604; and one or more second crosslinkable CTLs 605′ R/G/B/LC disposed between the second electrode 606 and the active layer 604. Each sub-pixel is separated from an adjacent sub-pixel by a bank structure 607, which further is depicted in the top view of FIG. 7. Again, one of the electrodes is semitransparent for the outcoupling of light from the R/G/B emissive active layers.

It will be appreciated that the sub-pixel arrangements of the pixels shown in FIGS. 6 and 7 are only schematic representations and not to scale, and that the spatial distribution of the sub-pixels on the substrate may not be linear as illustrated in the figures. Furthermore, each sub-pixel may differ from the others in terms of area, shape, layer and overall thickness, materials, and device structure (conventional or inverted; top emitting or bottom emitting).

An aspect of the invention, therefore, is a multifunction sub-pixel array device including an array of solution processed optoelectronic devices with different functionalities with optimized incorporation of a photo-crosslinkable material. In exemplary embodiments, a sub-pixel array device includes a plurality of optoelectronic devices disposed on a substrate, the plurality of optoelectronic devices including a light-emitting device and a light-converting device; and a bank structure that separates adjacent optoelectronic devices of the plurality of optoelectronic devices. Each of the plurality of optoelectronic devices comprises a first electrode, a second electrode, an active layer disposed between the first electrode and the second electrode and including a solution processable semiconductor, and a photo-crosslinkable material disposed between the first electrode and the second electrode. The sub-pixel array device may include one or more of the following features, either individually or in combination.

In an exemplary embodiment of the sub-pixel array device, the photo-crosslinkable material is incorporated within the active layer of each of the plurality of optoelectronic devices.

In an exemplary embodiment of the sub-pixel array device, the active layer of each of the plurality of optoelectronic devices comprises the solution processable semiconductor disposed within a matrix of the photo-crosslinkable material.

In an exemplary embodiment of the sub-pixel array device, the active layer of each of the plurality of optoelectronic devices further comprises a photo-initiator disposed within the matrix of the photo-crosslinkable material.

In an exemplary embodiment of the sub-pixel array device, the light-emitting device includes quantum dots as the solution processable semiconductor, and the quantum dots are dispersed within the matrix of the photo-crosslinkable material to form a photo-crosslinkable emissive layer.

In an exemplary embodiment of the sub-pixel array device, the matrix of the photo-crosslinkable material further includes a charge transport material to form a combined charge transport and emissive layer.

In an exemplary embodiment of the sub-pixel array device, the light-converting device includes a photo-active solution processable semiconductor, and the photo-active solution processable semiconductor is photo-crosslinkable or is incorporated within the matrix of the photo-crosslinkable material to form a photo-active layer.

In an exemplary embodiment of the sub-pixel array device, the photo-active layer include an electron donor semiconductor and an electron acceptor semiconductor, and the electron donor semiconductor and/or the electron acceptor semiconductor includes the photo-crosslinkable material.

In an exemplary embodiment of the sub-pixel array device, the photo-crosslinkable material is disposed between the active layer and the second electrode of each of the plurality of optoelectronic devices.

In an exemplary embodiment of the sub-pixel array device, each of the plurality of optoelectronic devices further comprises a capping layer disposed between the active layer and the second electrode, and the photo-crosslinkable material is incorporated into the capping layer.

In an exemplary embodiment of the sub-pixel array device, each of the plurality of optoelectronic devices further comprises a charge transport layer disposed between the active layer and the second electrode, and the photo-crosslinkable material is incorporated into the charge transport layer.

In an exemplary embodiment of the sub-pixel array device, the light-emitting device includes quantum dots as the solution processable semiconductor, and/or the light-converting device includes quantum dots as the solution processable semiconductor.

In an exemplary embodiment of the sub-pixel array device, the light-converting device is a solar cell.

In an exemplary embodiment of the sub-pixel array device, the light-converting device is a photodiode.

In an exemplary embodiment of the sub-pixel array device, each of the plurality of optoelectronic devices further comprises a first charge transport layer disposed between the active layer and the first electrode, and/or a second charge transport layer disposed between the active layer and the second electrode.

In an exemplary embodiment of the sub-pixel array device, one of the first electrode or the second electrode of each of the plurality of optoelectronic devices is semitransparent.

In an exemplary embodiment of the sub-pixel array device, the first electrode of each of the plurality of optoelectronic devices is disposed on the substrate oppositely from the active layer, and the first electrode and the substrate are semitransparent.

In an exemplary embodiment of the sub-pixel array device, one of the first electrode or the second electrode of each of the plurality of optoelectronic devices is an anode and the other of the first electrode or the second electrode is a cathode.

In an exemplary embodiment of the sub-pixel array device, the device include a plurality of light-emitting devices, wherein each of the plurality of light-emitting devices includes an active layer comprising an emissive layer having an emissive material that emits light of a different color.

In an exemplary embodiment of the sub-pixel array device, the plurality of light-emitting devices includes a red light-emitting device in which the emissive layer has an emissive material that emits red light, a green light-emitting device in which the emissive layer has an emissive material that emits green light, and a blue light-emitting device in which the emissive layer has an emissive material that emits blue light.

Although the invention has been shown and described with respect to a certain embodiment or embodiments, it is obvious that equivalent alterations and modifications will occur to others skilled in the art upon the reading and understanding of this specification and the annexed drawings. In particular regard to the various functions performed by the above described elements (components, assemblies, devices, compositions, etc.), the terms (including a reference to a “means”) used to describe such elements are intended to correspond, unless otherwise indicated, to any element which performs the specified function of the described element (i.e., that is functionally equivalent), even though not structurally equivalent to the disclosed structure which performs the function in the herein illustrated exemplary embodiment or embodiments of the invention. In addition, while a particular feature of the invention may have been described above with respect to only one or more of several illustrated embodiments, such feature may be combined with one or more other features of the other embodiments, as may be desired and advantageous for any given or particular application.

### INDUSTRIAL APPLICABILITY

Embodiments of the present application are applicable to many multifunction display devices the may emit light for a display function, and convert light for a light sensing or light harvesting function. Examples of such devices include multifunction monitors, mobile phones, personal digital assistants (PDAs), tablet and laptop computers, digital cameras, and like devices for which a high resolution display and light converting function are desirable.

1. A sub-pixel array device comprising:
a plurality of optoelectronic devices disposed on a substrate, the plurality of optoelectronic devices including a light-emitting device and a light-converting device; and
a bank structure that separates adjacent optoelectronic devices of the plurality of optoelectronic devices;
wherein each of the plurality of optoelectronic devices comprises a first electrode, a second electrode, an active layer disposed between the first electrode and the second electrode and including a solution processable semiconductor, and a photo-cross linkable material disposed between the first electrode and the second electrode.

2. The sub-pixel array device of claim 1, wherein the photo-cross linkable material is incorporated within the active layer of each of the plurality of optoelectronic devices.

3. The sub-pixel array device of claim 2, wherein the active layer of each of the plurality of optoelectronic devices comprises the solution processable semiconductor disposed within a matrix of the photo-cross linkable material.

4. The sub-pixel array device of claim 3, wherein the active layer of each of the plurality of optoelectronic devices further comprises a photo-initiator disposed within the matrix of the photo-cross linkable material.

5. The sub-pixel array device of claim 3, wherein the light-emitting device includes quantum dots as the solution processable semiconductor, and the quantum dots are dispersed within the matrix of the photo-cross linkable material to form a photo-cross linkable emissive layer.

6. The sub-pixel array device of any of claim 5, wherein the matrix of the photo-cross linkable material further includes a charge transport material to form a combined charge transport and emissive layer.

7. The sub-pixel array device of claim 3, wherein the light-converting device includes a photo-active solution processable semiconductor, and the photo-active solution processable semiconductor is photo-cross linkable or is incorporated within the matrix of the photo-cross linkable material to form a photo-active layer.

8. The sub-pixel array device of claim 7, wherein the photo-active layer include an electron donor semiconductor and an electron acceptor semiconductor, and the electron donor semiconductor and/or the electron acceptor semiconductor includes the photo-cross linkable material.

9. The sub-pixel array device of claim 1, wherein the photo-cross linkable material is disposed between the active layer and the second electrode of each of the plurality of optoelectronic devices.

10. The sub-pixel array device of claim 9, wherein each of the plurality of optoelectronic devices further comprises a capping layer disposed between the active layer and the second electrode, and the photo-cross linkable material is incorporated into the capping layer.

11. The sub-pixel array device of claim 9, wherein each of the plurality of optoelectronic devices further comprises a charge transport layer disposed between the active layer and the second electrode, and the photo-cross linkable material is incorporated into the charge transport layer.

12. The sub-pixel array device of claim 1, wherein the light-emitting device includes quantum dots as the solution processable semiconductor, and/or the light-converting device includes quantum dots as the solution processable semiconductor.

13. The sub-pixel array device of claim 1, wherein the light-converting device is a solar cell.

14. The sub-pixel array device of claim 1, wherein the light-converting device is a photodiode.

15. The sub-pixel array device of claim 1, wherein each of the plurality of optoelectronic devices further comprises a first charge transport layer disposed between the active layer and the first electrode, and/or a second charge transport layer disposed between the active layer and the second electrode.

16. The sub-pixel array device of claim 1, wherein one of the first electrode or the second electrode of each of the plurality of optoelectronic devices is semitransparent.

17. The sub-pixel array device of claim 1, wherein the first electrode of each of the plurality of optoelectronic devices is disposed on the substrate oppositely from the active layer, and the first electrode and the substrate are semitransparent.

18. The sub-pixel array device of claim 1, wherein one of the first electrode or the second electrode of each of the plurality of optoelectronic devices is an anode and the other of the first electrode or the second electrode is a cathode.

19. The sub-pixel array device of claim 1 including a plurality of light-emitting devices, wherein each of the plurality of light-emitting devices includes an active layer comprising an emissive layer having an emissive material that emits light of a different color.

20. The sub-pixel array device of claim 19, wherein the plurality of light-emitting devices includes a red light-emitting device in which the emissive layer has an emissive material that emits red light, a green light-emitting device in which the emissive layer has an emissive material that emits green light, and a blue light-emitting device in which the emissive layer has an emissive material that emits blue light.
